(19) United States
(12) Patent Application Publication
(10) Pub. No.: US 2026/0182224 A1
(43) Pub. Date: Jun. 25, 2026

(54) DISPLAY APPARATUS

(71) Applicant: LG Display Co., Ltd., Seoul (KR)

(72) Inventors: Min-Suk KONG, Paju-si (KR); Ji-Won KIM, Paju-si (KR)

(73) Assignee: LG Display Co., Ltd., Seoul (KR)

(21) Appl. No.: 19/210,995

(22) Filed: May 16, 2025

(30) Foreign Application Priority Data
Dec. 24, 2024 (KR) 10-2024-0195683

(51) Int. Cl. H10K 59/80; G09G 3/3233; H10K 59/131

(52) U.S. Cl. CPC H10K 59/879; H10K 59/131; G09G 3/3233; G09G 2300/0426; G09G 2300/0842

(57) ABSTRACT

A display apparatus according to the present disclosure comprises a substrate including a plurality of sub-pixels, a thin film transistor disposed in each sub-pixel, a first insulating layer covering the thin film transistor, a first signal line disposed on the first insulating layer, a second insulating layer on the first insulating layer to cover the first signal line, a plurality lens disposed on the second insulating layer in each sub-pixel, and an emitting device disposed on the second insulating layer that the plurality of lens are disposed, wherein the first signal line, among the plurality of first signal lines, having a width larger than the plurality of lens is disposed on the first insulating layer, and wherein the first signal line, among the plurality of first signal lines, having the width smaller than the plurality of lens is embedded in the first insulating layer.

### CROSS-REFERENCE TO RELATED APPLICATIONS

This application claims priority to Korean Patent Application No. 10-2024-0195683, filed in the Republic of Korea on Dec. 24, 2024, the entire contents of which is hereby expressly incorporated by reference into the present application.

### BACKGROUND

### Technical Field

The present disclosure relates to a display apparatus in which a planarization layer under a light emitting layer is planarized.

### Description of the Related Art

Recently, the importance of display apparatus has increased with the development of multimedia. Various display apparatus, such as liquid crystal display and organic light emitting displays, have been proposed. Among these display apparatus, an organic light emitting display apparatus is currently widely used because of a high response speed, high brightness, and a good viewing angle.

This organic light emitting display apparatus had a problem in that a significant portion of the light emitted from the light emitting layer was lost in the process of passing through various components of the display apparatus and being emitted to the outside, so that only about 20% of the light emitted from the light emitting layer was emitted to the outside of the display apparatus, resulting in a decrease in brightness.

### BRIEF SUMMARY

The inventors of the present disclosure have recognized that while increasing the current supplied to the light-emitting layer can enhance display brightness, it also leads to higher power consumption and a reduced device lifetime.

Accordingly, various embodiments of the present disclosure provide a display apparatus capable of preventing shape distortion and thickness deviation of a lens for improving light extraction by planarizing the upper surface of a planarization layer.

For example, various embodiments of the display apparatus selectively embed or dispose signal lines relative to a first insulating (planarization) layer based on a comparison between the width of the signal lines and the size of the microlenses. Narrower signal lines are embedded to flatten the planarization layer surface and prevent lens shape distortion, while wider signal lines are disposed on the surface without affecting lens formation. This structure maintains uniform microlens profiles, enhancing light extraction efficiency without increasing the thickness of the planarization layer or the overall device.

Signal line placement is further optimized by function: power lines requiring stable voltage supply are disposed on the surface, while reference voltage lines and light-emission signal lines are embedded. A two-layer planarization structure allows for vertical stacking of electrodes, reducing pixel area consumption and supporting compact, high-resolution display designs.

In order to achieve the technical benefits, an example display apparatus according to the present disclosure comprises a substrate including a plurality of sub-pixels, a thin film transistor disposed in each sub-pixel, a first insulating layer covering the thin film transistor, a first signal line disposed on the first insulating layer, a second insulating layer on the first insulating layer to cover the first signal line, a plurality lens disposed on the second insulating layer in each sub-pixel, and an emitting device disposed on the second insulating layer that the plurality of lens are disposed, wherein the first signal line, among the plurality of first signal lines, having a width larger than the plurality of lens is disposed on the first insulating layer, and wherein the first signal line, among the plurality of first signal lines, having the width smaller than the plurality of lens is embedded in the first insulating layer.

The first signal line embedded in the first insulating layer may be a power line and the first signal line disposed on the first insulating layer may be a reference voltage line and a light emitting signal line.

The sub-pixel where the first signal line is disposed on the first insulating layer may be a green sub-pixel and the sub-pixel where the first signal line is embedded in the first insulating layer may be a red sub-pixel and a green sub-pixel.

A connection pattern is disposed on the first insulating layer to connect the thin film transistor and the light emitting device, and the connection pattern may be made of the same material as the first signal line.

### BRIEF DESCRIPTION OF THE SEVERAL VIEWS OF THE DRAWINGS

FIG. 1 is a schematic block diagram of a display apparatus according to the present disclosure.

FIG. 2 is a schematic block diagram of a sub-pixel of the display apparatus according to the present disclosure.

FIG. 3 is the circuit diagram conceptually showing the sub-pixel of the display apparatus according to the present disclosure.

FIG. 4 is a sectional view of the display apparatus according to the present disclosure.

FIG. 5 is a drawing showing a case where a narrow signal line is formed on a first planarization layer.

FIG. 6 is a drawing showing a case where a narrow signal line is embedded in the first planarization layer.

FIG. 7 is a drawing showing a case where a wide signal line is formed on the first flattening layer.

### DETAILED DESCRIPTION

Advantages and features of the present disclosure and methods for achieving them will be made clear from embodiments described in detail below with reference to the accompanying drawings. The present disclosure may, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains, and the present disclosure is defined only by the scope of the appended claims.

Shapes, sizes, ratios, angles, numbers, and the like disclosed in the drawings for describing the embodiments of the present disclosure are illustrative, and thus the present disclosure is not limited to the illustrated matters. The same reference numerals refer to the same components throughout this disclosure. Further, in the following description of the present disclosure, when a detailed description of a known related art is determined to unnecessarily obscure the gist of the present disclosure, the detailed description thereof will be omitted herein. When terms such as “including,” “having,” “comprising,” and the like mentioned in this disclosure are used, other parts may be added unless the term “only” is used herein. When a component is expressed as being singular, being plural is included unless otherwise specified.

In analyzing a component, an error range is interpreted as being included even when there is no explicit description.

In describing a positional relationship, for example, when a positional relationship of two parts is described as being “on,” “above,” “below,” “next to,” or the like, unless “immediately” or “directly” is used, one or more other parts may be located between the two parts.

In describing a temporal relationship, for example, when a temporal predecessor relationship is described as being “after,” “subsequent,” “next to,” “prior to,” or the like, unless “immediately” or “directly” is used, cases that are not continuous may also be included.

Although the terms first, second, and the like are used to describe various components, these components are not substantially limited by these terms. These terms are used only to distinguish one component from another component. Therefore, a first component described below may substantially be a second component within the technical spirit of the present disclosure.

In describing the components of the disclosure, terms such as first, second, A, B, (a), (b), etc., may be used. These terms are only for distinguishing the elements from other elements, and the essence, order, or number of the elements is not limited by the terms. When it is described that a component is “coupled” or “connected” to another component, the component may be directly coupled or connected to the other component, but indirectly without specifically stated. It should be understood that other components may be “interposed” between each component that is connected or can be connected.

To elaborate, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

As used herein, the term “apparatus” may include a display apparatus such as a liquid crystal module (LCM) including a display panel and a driving unit for driving the display panel, and an organic light emitting display module (OLED module). Further, the term “apparatus” may further include a notebook computer, a television, a computer monitor, a vehicle electric apparatus including an apparatus for a vehicle or other type of vehicle, and a set electronic apparatus or a set apparatus such as a mobile electronic apparatus of a smart phone or an electronic pad, etc., which are a finished product (complete product or final product) including LCM and OLED module.

Accordingly, the apparatus in the disclosure may include the display apparatus itself such as the LCM, the OLED module, etc., and the application product including the LCM, the OLED module, or the like, or the set apparatus, which is the apparatus for end users.

Hereinafter, the disclosure will be described in detail with reference to the accompanying drawings.

This disclosure can be applied to the various display apparatus. For example, the display apparatus of this disclosure can be applied to various display apparatus such as an organic light emitting display apparatus, a liquid crystal display apparatus, an electrophoretic display apparatus, a quantum dot display apparatus, a micro LED (Light Emitting Device) display apparatus, and a mini LED display apparatus. However, in the following description, the organic light emitting display apparatus will be described as an example for convenience of explanation.

Hereinafter, the present disclosure will be described in detail with reference to the attached drawings.

The present disclosure can be adapted to various display apparatuses. For example, the display apparatus of the present disclosure can be adapted to various display apparatuses such as an organic light emitting display apparatus, a liquid crystal display apparatus, an electrophoretic display apparatus, a quantum dot display apparatus, a micro LED (Light Emitting Device) display apparatus, and a mini LED display apparatus. However, in the following description, an organic light emitting display apparatus is described as an example for convenience of explanation.

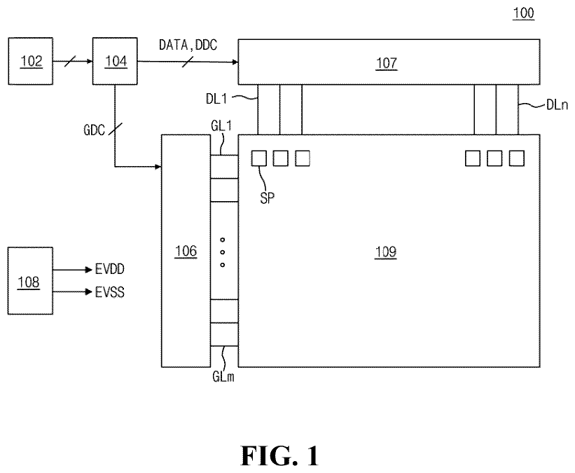

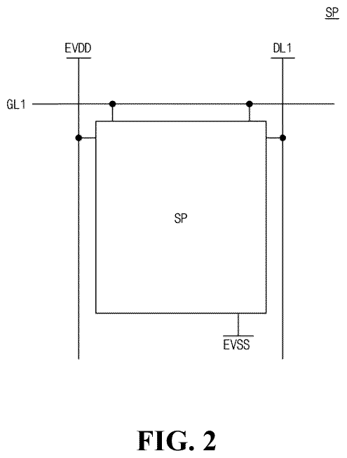

FIG. 1 is the schematic block diagram of a display apparatus 100 according to the present disclosure and FIG. 2 is the schematic block diagram of the sub-pixel SP shown in FIG. 1.

As shown in FIG. 1, the organic light emitting display apparatus 100 includes an image processing unit 102, a timing controlling unit 104, a gate driving unit 106, a data driving unit 107, a power supplying unit 108, and a display panel 109.

The image processing unit 102 outputs an image data supplied from outside and a driving signal for driving various devices. For example, the driving signal from the image processing unit 102 can include a data enable signal, a vertical synchronizing signal, a horizontal synchronizing signal, and a clock signal.

The image data and the driving signal are supplied to the timing controlling unit 104 from the image processing unit 102. The timing controlling unit 104 writes and outputs gate timing controlling signal GDC for controlling the driving timing of the gate driving unit 106 and data timing controlling signal DDC for controlling the driving timing of the data driving unit 107 based on the driving signal from the image processing unit 102.

The gate driving unit 106 outputs the scan signal to the display panel 109 in response to the gate timing control signal GDC supplied from the timing controlling unit 104. The gate driving unit 106 outputs the scan signal through a plurality of gate lines GL1 to GLm. In this case, the gate driving unit 106 may be formed in the form of an integrated circuit (IC), but is not limited thereto.

The data driving unit 107 outputs the data voltage to the display panel 109 in response to the data timing control signal DDC input from the timing controlling unit 104. The data driving unit 107 samples and latches the digital data signal DATA supplied from the timing controlling unit 104 to convert it into the analog data voltage based on the gamma voltage. The data driving unit 107 outputs the data voltage through the plurality of data lines DL1 to DLn. In this case, the data driving unit 107 may be mounted on the upper surface of the display panel 109 in the form of an integrated circuit (IC), but is limited thereto.

The power supplying unit 108 outputs a high potential voltage VDD and a low potential voltage VSS, etc., to supply these to the display panel 109. The high potential voltage VDD is supplied to the display panel 109 through the first power line EVDD and the low potential voltage VSS is supplied to the display panel 109 through the second power line EVSS. In this time, the voltage from the power supplying unit 108 are applied to the data driving unit 107 or the gate driving unit 106 to drive thereto.

The display panel 109 displays the image based on the data voltage from the data driving unit 108, the scan signal from the gage driving unit 106, and the power from the power supplying unit 108.

The display panel 109 includes a plurality of sub-pixels SP to display the image. The sub-pixel SP can include Red sub-pixel, Green sub-pixel, and Blue sub-pixel. Further, the sub-pixel SP can include White sub-pixel, the Red sub-pixel, the Green sub-pixel, and the Blue sub-pixel. The White sub-pixel, the Red sub-pixel, the Green sub-pixel, and the Blue sub-pixel may be formed in the same area or may be formed in different areas.

As shown in FIG. 2, one sub-pixel SP may be connected to the gate line GL1, the data line DL1, the first power line EVDD, and the second power line EVSS. The sub-pixel SP may include a plurality of thin film transistors and a storage capacitor depending on the configuration of the pixel circuit.

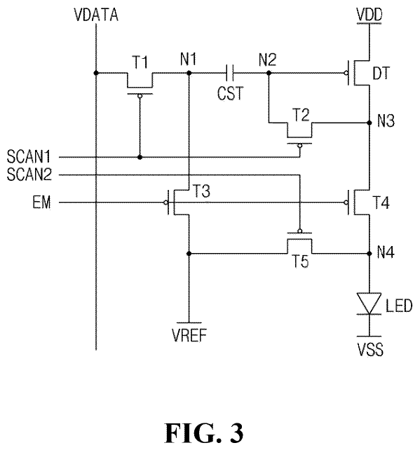

FIG. 3 is the circuit diagram and the plan view of the sub-pixel SP of the organic light emitting display apparatus 100 according to the present disclosure. In the drawing, the pixel circuit arranged in one sub-pixel SP is depicted as having a circuit structure of 6T1C including six transistors and one capacitor. However, this is an example, and the number of transistors and capacitors constituting the pixel circuit are not limited thereto.

As shown in FIG. 3, one sub-pixel SP includes a first transistor T1, a second transistor T2, a third transistor T3, a fourth transistor T4, a fifth transistor T5, a driving transistor DT, a storage capacitor CST, and a light emitting device D.

The light emitting device D emits the light by a driving current supplied from the driving transistor DT. An anode of the light emitting device D is connected to the fourth node N4, and the cathode of the light emitting device D is connected to an input terminal of a low potential voltage VSS.

The driving transistor DT controls the driving current applied to the light emitting device D according to the voltage Vsg between a source electrode and a gate electrode. The source electrode of the driving transistor DT is connected to the input terminal of the high potential voltage VDD, the gate electrode is connected to the second node N2, and a drain electrode is connected to the third node N3.

The first transistor T1 includes the gate electrode connected to a first scan signal (SCAN1) input terminal, the source electrode connected to the data line DL supplying the data voltage VDATA, and the drain electrode connected to the first node N1. The first transistor T1 can apply the data voltage VDATA supplied from the data line DL to the first node N1 in response to the first scan signal SCAN1.

The second transistor T2 includes the source electrode connected to the third node N3, the drain electrode connected to the second node N2, and the gate electrode connected to the first scan signal SCAN1 input terminal. The second transistor T2 can diode-connect the gate electrode and the drain electrode of the driving transistor DT in response to the first scan signal SCAN1.

The third transistor T3 includes the gate electrode connected to an emission signal EM input terminal, the source electrode connected to the first node N1, and the drain electrode connected to a reference voltage Vref input terminal. The third transistor T3 can apply the reference voltage VREF to the first node N1 in response to the emission signal EM.

The fourth transistor T4 includes the source electrode connected to the third node N3, the drain electrode connected to the fourth node N4, and the gate electrode connected to the emission signal EM input terminal. The fourth transistor T4 forms a current path between the third node N3 and the fourth node N4 in response to the emission signal EM.

The fifth transistor T5 includes the drain electrode connected to the fourth node N4, the source electrode connected to the reference voltage Vref input terminal, and the gate electrode connected to the second scan signal SCAN2 input terminal. The fifth transistor T5 can apply the reference voltage Vref to the fourth node N4 in response to the second scan signal SCAN2.

A storage capacitor CST includes a first electrode connected to the first node N1 and a second electrode connected to the second node N2.

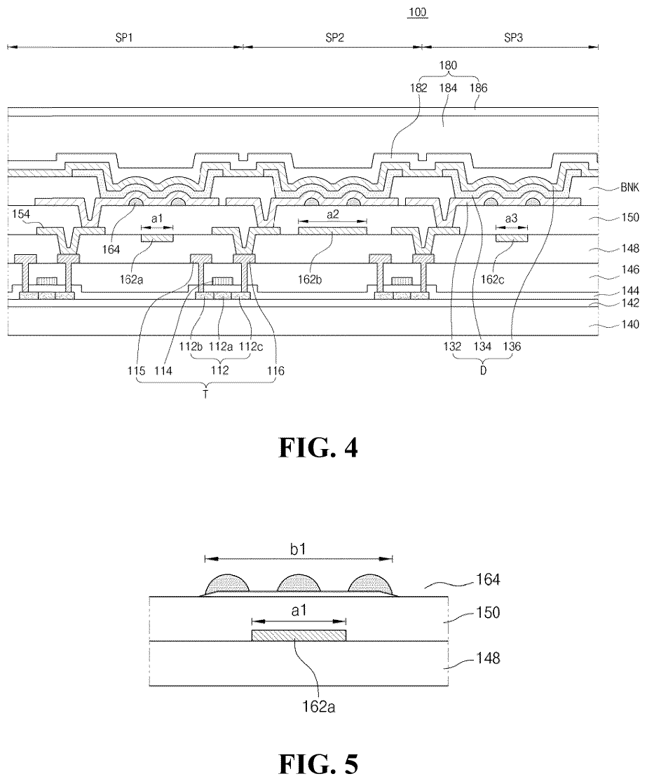

FIG. 4 is a cross-sectional view showing the display apparatus 100 according to the present disclosure.

As shown in FIG. 4, the substrate 140 includes first to third sub-pixels SP1, SP2, SP3. Each of the first to third sub-pixels SP1, SP2, SP3 may be a red sub-pixel, a blue sub-pixel, and a green sub-pixel, but is not limited thereto.

The substrate 140 may be made of a hard material such as a glass or a flexible plastic material.

When the substrate 140 is made of the plastic material, the substrate 140 may be made of at least one of a polyimide, a polymethylmethacrylate, a polyethylene tereththalate, a Polyethersulfone, and a Polycarbonate, but not limited thereto

When the substrate 140 is made of polyimide, the substrate 140 may be made of a plurality of polyimide layers, and an inorganic layer may be further disposed between the polyimide layers, but is not limited thereto.

A buffer layer is formed on the substrate 140. The buffer layer 142 may be formed in the entire area of the substrate 140 to enhance adhering force between the substrate 140 and the layers thereon. Further, the buffer layer 142 may block various types of defects, such as alkali components flowing out from the substrate 140. In addition, the buffer layer 142 may delay diffusion of moisture or oxygen penetrating into the substrate 140.

The buffer layer 142 may be a single layer made of silicon oxide (SiOx) or silicon nitride (SiNx), or multi-layers thereof. When the buffer layer 142 is made of multiple layers, SiOx and SiNx may be alternately formed. The buffer layer 142 may be omitted based on the type and material of the substrate 140, the structure and type of the thin film transistor, and the like.

A thin film transistor is formed on the buffer layer 142 in the display area AA. For convenience of description, only the driving thin film transistor among various thin film transistors that may be disposed in the display area AA is illustrated, but other thin film transistors such as switching thin film transistors may also be included. In the figure, the thin film transistor of a top gate structure is shown, but the thin film transistor is not limited to this structure and may be formed in other structures such as the thin film transistor of a bottom gate structure.

The thin film transistor includes a semiconductor layer 112 disposed on the buffer layer 142, a gate insulating layer 144 covering the semiconductor layer 112, the gate electrode 114 on the gate insulating layer 144, an interlayer insulating layer 146 covering the gate electrode 114, and the source electrode 115 and the drain electrode 116 on the interlayer insulating layer 146.

The semiconductor pattern 112 may be made of a polycrystalline semiconductor. For example, the polycrystalline semiconductor may be made of low temperature poly silicon (LTPS) having high mobility, but is not limited thereto.

The semiconductor pattern 112 may be made of an oxide semiconductor. For example, semiconductor pattern 112 may be made of one of IGZO (Indium-gallium-zinc-oxide), IZO (Indium-zinc-oxide), IGTO (Indium-gallium-tin-oxide), and IGO (Indium-gallium-oxide), but is not limited thereto. The semiconductor pattern 112 includes a channel region 112a in a central region and a source region 112b and a drain region 112c which are doped layers at the both sides of the channel region 112a.

The gate insulating layer 144 may be composed of a single layer or multiple layers made of an inorganic material such as SiOx or SiNx, but is not limited thereto.

The gate electrode 114 is made of a metal. For example, the gate electrode 113 may be formed of the single layer or multi layers made of one or alloys of molybdenum (Mo), aluminum (Al), chromium (Cr), gold (Au), titanium (Ti), nickel (Ni), neodymium (Nd), and copper (Cu), but is not limited thereto.

The interlayer insulating layer 146 may be made of the organic material such as photo-acryl, or the interlayer insulating layer 146 may formed of the single layer or the multiple layers made of the inorganic material such as SiOx or SiNx, but is not limited thereto. Further, the interlayer insulating layer 146 may be formed of the multi layers of the organic material layer and the inorganic material layer, but is not limited thereto.

The source electrode 115 and the drain electrode 116 are formed of the single layer or multi layers made of one or alloys of molybdenum (Mo), aluminum (Al), chromium (Cr), gold (Au), titanium (Ti), nickel (Ni), neodymium (Nd), and copper (Cu), but is not limited thereto. The source electrode 114 and the drain electrode 115 may be respectively contacted to the source region 112b and the drain region 112c of the semiconductor through contact holes formed in the gate insulating layer 144 and the interlayer insulating layer 146.

Although not shown in figure, a bottom shield metal layer may be disposed on the substrate 140 under the semiconductor pattern 112. The bottom shield metal layer minimizes a backchannel phenomenon caused by charges trapped in the substrate 140 to prevent afterimages or deterioration of transistor performance. The bottom shield metal layer may be composed of the single layer or the multi layers made of titanium (Ti), molybdenum (Mo), or an alloy thereof, but is not limited thereto.

A first planarization layer 148 is formed on the substrate where the thin film transistor is disposed. The first planarization layer 148 may be formed of the organic material such as photoacrylic, but it is not limited thereto. The first planarization layer 148 may include a plurality of layers including the inorganic layer and the organic layer.

A connection pattern 154 is disposed on the first planarization layer 148 and is electrically connected to the drain electrode 116 of the thin film transistor T through a contact hole formed in the first planarization layer 148. The connection pattern 154 may be made of metal.

Further, first to third signal lines 162a, 162b, and 162c are disposed on the first planarization layer 148. The first to third signal lines 162a, 162b, and 162c are formed in the first to third sub-pixels SP1, SP2, and SP3, respectively. At this time, the first signal line 162a and the third signal line 162c may be embedded in the first planarization layer 148, and the second signal line 162b may be formed on the upper surface of the first planarization layer 148.

The first to third signal lines 162a, 162b, and 162c may be the reference voltage line for supplying the reference voltage (Vref), the power line for supplying the high-potential voltage, and the light emitting signal line for supplying the light emitting signal, respectively. However, this is not limited thereto, and the first to third signal lines 162a, 162b, and 162c may be any one of the reference voltage line, the power line, and the light-emitting signal line, respectively.

In the present disclosure, the width a2 of the second signal line 162b disposed on the first planarization layer 148 is larger than the width a1 of the first signal line 162a and the width a3 of the third signal line 163c embedded in the first planarization layer 148 (a2>a1, a3), and the reason for this will be explained in detail later.

The connection pattern 154 and the first to third signal lines 162a, 162b, and 162c may be formed of the same metal by the same fabrication process, but may also be formed of different metals by different fabrication processes.

A second planarization layer 150 is formed on the first planarization layer 148 on which a connection pattern 154 is formed. The second planarization layer 150 may be formed of the organic material such as photoacrylic, but it is not limited thereto. The second planarization layer 150 may include a plurality of layers including the inorganic layer and the organic layer. The second planarization layer 150 may include a plurality of layers including the inorganic layer and the organic layer.

In the present disclosure, by forming the planarization layer in a two-layer structure 148 and 150, various electrodes and signal lines can be formed between the first and second planarization layers 148 and 150. Accordingly, since the electrodes can be arranged vertically, the area due to the electrodes and signal line in the sub-pixel can be reduced, and as a result the area of the sub-pixel can be reduced for a high-resolution display apparatus 100.

A light emitting device D is disposed on the second planarization layer 158. The light emitting device D includes a first electrode 132, an organic layer 134, and a second electrode 136.

The first electrode 132 is disposed on the second planarization layer 150 and electrically connected to the drain electrode 115 of the thin film transistor through the contact hole formed in the second planarization layer 148. The first electrode 132 may be formed of at least one of silver (Ag), aluminum (Al), gold (Au), molybdenum (Mo), tungsten (W), chromium (Cr), or an alloy thereof.

Further, the first electrode 132 may be formed of a transparent metal oxide material such as indium tin oxide (ITO) or indium zinc oxide (IZO). When the first electrode 132 is made of the transparent metal oxide layer, the first electrode 132 may further include an opaque conductive material to function as a reflective electrode that reflects light.

A bank layer BNK is formed at the boundary between the sub-pixels on the second planarization layer 150. The bank layer 152 may be a barrier wall to define sub-pixels. The bank layer BNK divides each sub-pixel to prevent light of a specific color output from adjacent pixels from being mixed and output.

The bank layer BNK is made of at least one material of the inorganic insulating material such as SiNx or SiOx, the organic insulating material such as BenzoCycloButene, acrylic resin, epoxy resin, phenolic resin, polyamide resin, or the photosensitizer including black pigment, but is not limited thereto.

The light emitting layer 134 may be formed in the R, G, and B pixels and may include an R-emitting layer that emits red light, a G-emitting layer that emits green light, and a B-emitting layer that emits blue light. For example, the light emitting layer 134 may include an organic light emitting layer, an inorganic light emitting layer, a nano-sized material layer, a quantum dot, a micro LED light emitting layer, or a mini LED light emitting layer, but is not limited thereto.

The light emitting layer 134 may further include an electron injecting layer for injecting electrons into the light emitting layer, a hole injecting layer for injecting holes into the light emitting layer, an electron transporting layer for transporting the injected electrons to the light emitting layer, a hole transporting layer for transporting the injected holes to the light emitting layer, an electron blocking layer, and a hole blocking layer, but is not limited thereto.

The second electrode 136 is disposed on the light emitting layer 134 and may be formed of the half-transparent conductive material that transmits light. For example, the second electrode 188 may be made of at least one or more of the alloys such as LiF/Al, CsF/Al, Mg:Ag, Ca/Ag, Ca:Ag, LiF/Mg:Ag, LiF/Ca/Ag, or LiF/Ca:Ag. Further, the second electrode 136 may be made of a transparent metal oxide such as indium tin oxide (ITO) or indium zinc oxide (IZO), but is not limited thereto.

Further, the light emitting device D may be formed in a tandem structure. The tandem structure may include a plurality of organic light emitting layers and a charge generating layer disposed between the organic light emitting layers. The charge generating layer is disposed to adjust the charge balance between the plurality of organic light emitting layers, and may be formed of a plurality of layers including a first charge generating layer and a second charge generating layer. The charge generating layer may include an N-type charge generating layer and a P-type charge generating layer. In this case, the charge generating layer may be formed of the organic layer doped with an alkali metal such as Li, Na, K, or Cs or an alkaline earth metal such as Mg, Sr, Ba, or Ra, but is not limited thereto.

Meanwhile, a plurality of lenses 164 are disposed on the second planarization layer 150 of each of the first to third sub-pixels SP1, SP2, and SP3, and the first electrode 132 of the light emitting device D is disposed on the second planarization layer 150 and the lens 164. In the drawing, two lenses 164 are disposed in each of the first to third sub-pixels SP1, SP2, and SP3, but this is for convenience of explanation. In practice, the arrangement of the plurality of lenses 164 may be dependent upon the area of the first to third sub-pixels SP1, SP2, and SP3 and the size of the lenses 164.

The lens 164 improves the light extraction efficiency of the display apparatus 100. When the light emitted from the light emitting layer 134 is output to the outside, some of the light is totally reflected at the interface between the light emitting layer 134 and the second electrode 136. Further, the light emitted from the light emitting layer 134 and output downward is totally reflected at the interface between the light emitting layer 134 and the first electrode 132. The light totally reflected at the interface between the light emitting layer 134 and the second electrode 136 and the interface between the light emitting layer 13) and the first electrode 132 is trapped inside the light emitting layer 134 to that the light is not extracted to the outside.

In the present disclosure, however, since the lens 164 is formed the first to third sub-pixels SP1, SP2, and SP3, the light totally reflected inside the light emitting layer 134 propagates at an angle smaller than the total reflection critical angle. Accordingly, the light is multi reflected and output to the outside, so that the light emission efficiency of the display apparatus 100 can be increased.

The lens 164 may be made of the organic material having a high refractive index. For example, the lens 164 may be made of one of an acrylic resin, an epoxy resin, a phenol resin, a polyamide resin, a polyimide resin, an unsaturated polyester resin, a polyphenylene resin, a polyphenylene sulfide resin, benzocyclobutene, and a photoresist,, but is not limited thereto.

Am encapsulation layer 180 is formed on the light emitting device D to seal the light emitting device D. When the light emitting device D is exposed to impurities such as moisture or oxygen, a pixel shrinkage phenomenon in which the light emitting area is reduced or the defect such as a dark spot in the light emitting area may occur. Further, moisture or oxygen penetrating into the light emitting device D oxidizes the metal electrode. The encapsulation layer 180 blocks impurities such as the oxygen and the moisture from the outside to prevent defects of the light emitting device D and various electrodes.

The encapsulation layer 180 may be formed of a first encapsulation layer 182, a second encapsulation layer 184, and a third encapsulation layer 186, but is not limited thereto. The encapsulation layer 180 may be formed of two layers or four or more layers.

The first encapsulation layer 182 and the third encapsulation layer 186 may be formed of a single layer or multiple layers including the inorganic materials such as SiOx, SiON, SiNx, etc. In this case, the organic material may be further included between the inorganic materials such as SiOx, SiON, SiNx, etc., but is not limited thereto. The second encapsulation layer 184 may be made of an epoxy resin.

Although not shown in figure, a touch member may be disposed on the encapsulation layer 180. The touch member can detect external touch information using the user's finger or a touch pen.

As described above, in the present disclosure, some of the signal lines 162a, 162b, and 162c are embedded in the first planarization layer 148 for the following reasons.

FIG. 5 is the drawing showing a case where the signal line 162a is formed on the first planarization layer 148.

As shown in FIG. 5, since the first planarization layer 148 is formed on the signal line 162a, the upper surface of the first planarization layer 148 is not flattened by the signal line 162a and the surface becomes curved. When a plurality of lenses 164 are formed, the curvature of the upper surface of the first planarization layer 148 not only causes the distortion in the shape of the lenses 164, but also causes the thickness deviation between the plurality of lenses 164.

Due to the shape distortion of the lens 164 and the thickness difference between the plurality of lenses 164, when the light emitted from the light emitting layer 134 is propagated in the light emitting layer 134, the light does not proceed at an angle smaller than the critical angle of the total reflection but proceeds at an angle larger than the critical angle through some lenses 164, so that the external extraction efficiency of the light is decreased.

In order to flatten the upper surface of the first planarization layer 148, the thickness of the first planarization layer 148 can be increased. In this case, as the thickness of the first planarization layer 148 is increased, the thickness of the entire display apparatus 100 is increased, the formation time of the first planarization layer 148 is delayed, and the manufacturing cost is increased. Further, the use of excessive organic materials to form the thick first planarization layer 148 causes the environmental pollution.

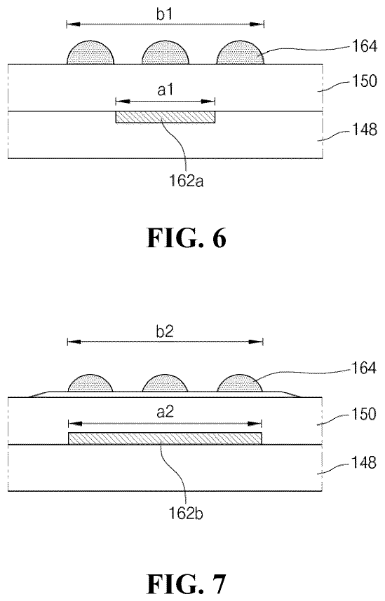

In the display apparatus 100 according to the present disclosure, as shown in FIG. 6, since the signal line 162a is embedded in the first planarization layer 148, the upper surface of the first planarization layer 148 can be flattened without increasing the thickness of the first planarization layer 148, and as a result the external extraction efficiency of light can be increased.

Meanwhile, in the display apparatus 100 according to the present disclosure, some signal lines 162a and 162c are embedded in the first planarization layer 148, but some signal lines 162b are formed on the upper surface of the first planarization layer 148. The reason for this is as follows.

The reason why the signal lines 162a and 162c are embedded in the first planarization layer 148 is because the upper surface of the first planarization layer 148 is curved by the signal lines 162a and 162c. Since the curve is caused by the step of the signal lines 162a and 162c, the curved area corresponds to both sides of the signal lines 162a and 162c.

As shown in FIG. 5, when the area b1 where the multiple lenses 164 are formed is larger than the width a1 of the signal lines 162a and 162c (b1>a1), some of the multiple lenses 162a and 162c are formed in areas corresponding to both sides of the signal lines 162a and 162c, so that the shape distortion and the thickness deviation of the lens 164 occur. Therefore, in this case, as shown in FIG. 6, by embedding the signal lines 162a and 162c in the first planarization layer 148, the shape distortion and the thickness deviation of the lens 164 can be prevented.

On the other hand, as shown in FIG. 7, when the area b2 where the multiple lenses 164 are formed is smaller than the width a2 of the signal line 162b (b2<a2), the multiple lenses 162b are not formed in areas corresponding to both sides of the signal line 162b. Accordingly, the shape distortion and the thickness deviation of the lens 164 do not occur in this case, even if the signal line 162b is not embedded in the first planarization layer 148, the shape distortion and the thickness deviation of the lens 164 do not occur.

As described above, in the display apparatus 100 according to the present disclosure, the signal lines 162a, 162b, and 162c can be embedded in the first planarization layer 148 according to the size of the width of the signal lines 162a, 162b, and 162c, so that the shape distortion and the thickness deviation of the lens 164 can be prevented.

Referring again to FIG. 4, in the present disclosure, the first and third signal lines 162a and 162c are embedded in the first flat planarization layer 148, and the second signal line 162b is disposed on the upper surface of the first planarization layer 148. At this time, the first and third signal lines 162a and 162c may be the light emitting signal line for applying the light emitting signal and the reference voltage line for applying the reference voltage (Vref), respectively, and the second signal line 162b may be the power line for applying the high potential voltage. In general, in order to drive the display apparatus 100 stably, the voltage must be supplied stably. Accordingly, there is no problem in stably driving the display apparatus 100 even if the power line is formed with the maximum width while other signal lines are formed with the relatively small width.

That is, in the present disclosure, the second signal line 162b disposed above the power line that applies the high potential voltage is disposed on the upper surface of the first planarization layer 148, and the other signal lines 162a and 162c are embedded inside the first planarization layer 148. However, the present disclosure is not limited to this configuration.

Further, in the present disclosure, the second sub-pixel SP2 in which the second signal line 162b is disposed may be the green sub-pixel, and the first and third sub-pixels SP1 and SP3 in which the first and third signal lines 162a and 162c are disposed may be the red sub-pixel and the blue sub-pixel, respectively, but this is not limited thereto.

Meanwhile, in the above-described description, the signal lines 162a, 162b, and 162c are formed on the first planarization layer 148, but the signal lines 162a, 162b, and 162c may be formed on the interlayer insulating layer 146 rather than the first planarization layer 148. Further, the signal lines 162a, 162b, and 162c may be formed on both the first planarization layer 148 and the interlayer insulating layer 146.

Even at this time, the first and third signal lines 162a and 162c may be embedded in the first planarization layer 148 and/or the interlayer insulating layer 146, and the second signal line 162b may be disposed on the upper surface of the first planarization layer 148 and/or the interlayer insulating layer 146.

As described above, in the present disclosure, the signal line is embedded in the first planarization layer or disposed on the upper surface of the first planarization layer depending on the width of the signal line, thereby preventing the occurrence of the shape distortion and the thickness deviation of the lens, and thus preventing a decrease in the external extraction efficiency of light.

The above description and the accompanying drawings are merely illustrative of the technical spirit of the present disclosure, and those of ordinary skill in the art to which the present disclosure pertains can combine configurations within a range that does not depart from the essential characteristics of the present disclosure, various modifications or variations such as separation, substitution and alteration will be possible. Therefore, the embodiments disclosed in the present disclosure are not intended to limit the technical spirit of the present disclosure, but to explain, and the scope of the technical spirit of the present disclosure is not limited by these embodiments.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus, comprising:
a substrate including a plurality of sub-pixels;
a thin film transistor disposed in each sub-pixel;
a first insulating layer covering the thin film transistor;
a first signal line on the first insulating layer;
a second insulating layer on the first insulating layer to cover the first signal line;
a plurality lens on the second insulating layer in each sub-pixel; and
an emitting device on the second insulating layer that the plurality of lens is disposed,
wherein the first signal line, among the plurality of first signal lines, having a width larger than the plurality of lens is on the first insulating layer, and
wherein the first signal line, among the plurality of first signal lines, having the width smaller than the plurality of lens is embedded in the first insulating layer.

2. The display apparatus of claim 1, wherein the first signal line embedded in the first insulating layer includes a power line.

3. The display apparatus of claim 1, wherein the first signal line disposed on the first insulating layer includes a reference voltage line and a light emitting signal line.

4. The display apparatus of claim 1, wherein the sub-pixel where the first signal line is on the first insulating layer is a green sub-pixel and the sub-pixel where the first signal line is embedded in the first insulating layer is a red sub-pixel and a green sub-pixel.

5. The display apparatus of claim 1, further comprising a connection pattern on the first insulating layer to connect the thin film transistor and the light emitting device.

6. The display apparatus of claim 5, wherein the connection pattern is made of the same material as the first signal line.

7. The display apparatus of claim 1, wherein the thin film transistor includes:
a semiconductor layer on the substrate;
a gate insulating layer on the semiconductor layer;
a gate electrode on the gate insulating layer;
an interlayer insulating layer on the gate electrode; and
a source electrode and a drain electrode on the interlayer insulating layer.

8. The display apparatus of claim 7, further comprising a plurality of second signal lines on the interlayer insulating layer in each sub-pixel.

9. The display apparatus of claim 8, wherein the second signal line, among the plurality of second signal lines, having the width larger than the plurality of lens is disposed on the interlayer insulating layer, and
wherein the second signal line, among the plurality of second signal lines, having the width smaller than the plurality of lens is embedded in the interlayer insulating layer.

10. The display apparatus of claim 1, wherein embedding the first signal line having a width smaller than the plurality of lenses planarizes an upper surface of the first insulating layer.

11. The display apparatus of claim 1, wherein the plurality of lenses comprises an organic material having a refractive index greater than that of the second insulating layer.
